(19) United States
(12) Patent Application Publication
(10) Pub. No.: US 2026/0282418 A1
(43) Pub. Date: Sep. 17, 2026

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventor: Yoshitaka KAMO, Tokyo (JP)

(73) Assignee: Mitsubishi Electric Corporation, Tokyo (JP)

(21) Appl. No.: 19/473,706

(22) PCT Filed: Jul. 20, 2023
(86) PCT No.: PCT/JP2023/026521

§ 371 Date: Oct. 8, 2025

(51) Int. Cl. H10D 30/47; H10D 30/01; H10D 62/10; H10D 62/824; H10P 32/10

(52) U.S. Cl. CPC H10D 30/475; H10D 30/015; H10D 62/102; H10D 62/824; H10P 32/174

(57) ABSTRACT

It is difficult to stably manufacture a conventional GaN-based HEMT which has an AlN spacer layer below the source and drain electrodes to reduce access resistance and does not have the AlN spacer layer directly below the gate electrode to reduce gate leakage current. A method for manufacturing a semiconductor device according to the present disclosure having a GaN-based HEMT includes: forming a metal film (21) on an epitaxial wafer (10); forming an opening portion (31) in the metal film (21) corresponding to a position where a gate electrode (18) is formed; and irradiating the opening portion (31) with a laser (90) to anneal the spacer layer (13) and the channel layer (12).

### FIELD

The present disclosure relates to a semiconductor device and a method for manufacturing the semiconductor device, particularly to a GaN-based HEMT including an AlN layer.

### BACKGROUND

A GaN (gallium nitride)-based HEMT (High Electron Mobility Transistor) including an AlN (aluminum nitride) spacer is widely known. Patent Literature 1 discloses a GaN-based HEMT in which, while an AlN spacer layer is provided in a portion except directly below a gate electrode between a source electrode and a drain electrode to reduce access resistance, the AlN spacer layer is not present directly below the gate electrode to reduce a gate leakage current. In Patent Literature 1, after the AlN spacer layer in a region directly below the gate electrode is removed by etching, a barrier layer is regrown in a portion upper than a channel layer and the AIN spacer layer.

### CITATION LIST

### Patent Literature

[PTL 1] Japanese Patent No. 5744346

### SUMMARY

### Technical Problem

In General, the thickness of a spacer layer in a GaN-based HEMT is very small, and 1 nm in Patent Literature 1, for example. In Patent Literature 1, this thin spacer layer is removed by etching only directly below a gate.

In a semiconductor manufacturing step, the amount of etching is controlled by etching time, but from a practical standpoint, it is inevitable that the etching rate will vary regardless of dry etching or wet etching. Because of this, when it is intended to remove a thin layer by etching, the following is generally conducted: an etch stop layer whose etching rate is lower than the layer to be removed is provided at the back thereof to stop etching, whereby a manufacture margin is ensured and production is stabilized.

However, in Patent Literature 1, a GaN channel layer is present below the AlN spacer layer. The etching rate of GaN is significantly higher than that of AlN. Because of this, when etching is continued after etching of the AlN spacer layer is finished, the GaN channel layer is easily over-etched. Thus, it is practically very difficult to remove only the AlN channel layer stably by etching when the uniformity in a wafer surface or the like is taken into consideration. Further, in the case of providing the etch stop layer between the AlN spacer layer and the GaN channel layer, there is difficulty because the influence appears on the formation of a two-dimensional electron gas, i.e., the operation of the GaN-based HEMT itself.

Therefore, it has been very difficult to stably manufacture the GaN-based HEMT disclosed in Patent Literature 1.

The present disclosure has been made in view of the above-described problem, and an object of the present disclosure is to provide a method for manufacturing a GaN-based HEMT in which access resistance is reduced and a gate leakage current is reduced while avoiding the difficulty of removing an AIN spacer layer by etching. Another object of the present disclosure is to provide a GaN-based HEMT in which access resistance is reduced and a gate leakage current is reduced.

### Solution to Problem

A method for manufacturing a semiconductor device according to the present disclosure having a GaN-based HEMT includes: forming an epitaxial wafer including a channel layer and a spacer layer formed in contact with the channel layer; forming a metal film on the epitaxial wafer; forming an opening portion in the metal film; irradiating the opening portion with a laser to anneal the spacer layer and the channel layer; and forming a gate electrode in the opening portion.

A semiconductor device according to the present disclosure having a GaN-based HEMT includes: an epitaxial wafer having a channel layer formed on a substrate and a spacer layer on the channel layer; and a gate electrode formed on the epitaxial wafer, wherein the channel layer below the gate electrode contains Al diffused from the spacer layer, and the channel layer other than below the gate electrode does not contain Al diffused from the spacer layer.

### Advantageous Effects of Invention

According to the present disclosure, a method for manufacturing a GaN-based HEMT with reduced access resistance and reduced gate leakage current is provided while avoiding the difficulty of removing the AlN spacer layer by etching. Furthermore, according to the present disclosure, a GaN-based HEMT with reduced access resistance and reduced gate leakage current is provided.

### BRIEF DESCRIPTION OF THE DRAWINGS

FIG. 1 is a cross-sectional view showing a semiconductor device 100 according to Embodiment 1 of the present invention.

FIG. 2 is a figure showing a method for manufacturing the semiconductor device 100 according to Embodiment 1 of the present invention.

FIG. 3 is a figure showing a method for manufacturing the semiconductor device 100 according to Embodiment 1 of the present invention.

FIG. 4 is a figure showing a method for manufacturing the semiconductor device 100 according to Embodiment 1 of the present invention.

FIG. 5 is a figure showing a method for manufacturing the semiconductor device 100 according to Embodiment 1 of the present invention.

FIG. 6 is a cross-sectional TEM image of the epitaxial wafer 10.

FIG. 7 shows the result of elementary analysis of the epitaxial wafer before annealing.

FIG. 8 shows the result of elementary analysis of the epitaxial wafer after annealing.

### DESCRIPTION OF EMBODIMENTS

### Embodiment

A power amplifier according to an embodiment of the present disclosure is described with reference to drawings. Like or corresponding elements are denoted by the same numerals and repetitive description is omitted in some cases.

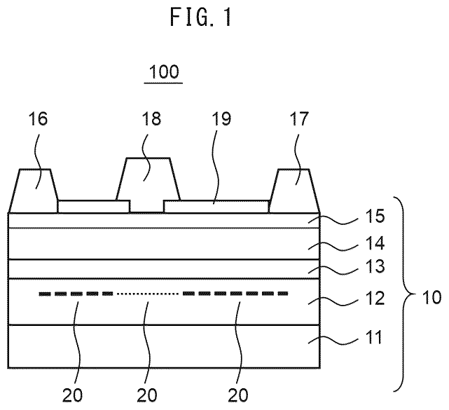

FIG. 1 is a cross-sectional view showing a semiconductor device 100 according to Embodiment 1 of the present invention.

The semiconductor device 100 is a GaN-based HEMT formed in an epitaxial wafer 10.

The epitaxial wafer 10 includes a substrate 11, a channel layer 12, a spacer layer 13, a barrier layer 14, and a cap layer 15. The substrate 11 is made of semi-insulating SiC (silicon carbide). The thickness of the substrate 11 is 100 μm, for example, and an upper surface thereof is a (0001) plane, for example. A material of the substrate 11 may be monolithic sapphire or the like.

The channel layer 12 made of GaN is formed above a surface side of the substrate 11.

Above the channel layer 12, the spacer layer 13 is formed in contact with the channel layer 12. A material of the spacer layer 13 is AlN, and the thickness thereof is extremely small. Specifically, the thickness thereof is preferably less than or equal to 10 nm, more preferably greater than or equal to 0.5 nm and less than or equal to 1.5 nm.

The barrier layer 14 made of AlGaN (aluminum gallium nitride) is formed above the spacer layer 13.

The cap layer 15 made of GaN is formed above the barrier layer 14.

A source electrode 16, a drain electrode 17, and a gate electrode 18 are provided in contact with the cap layer 15. The other portion of the cap layer 15 is covered with a protection film 19 mainly made of SiN (silicon nitride).

Note that the channel layer 12 may be laminated after a nucleation layer or a buffer layer is laminated above the substrate 11. The nucleation layer may be a thin layer made of AlN, and the buffer layer may be a layer made of GaN or AlGaN.

It is well known that a two-dimensional electron gas 20, which is called 2DEG, is generated at the interface between the channel layer 12 made of GaN and the spacer layer 13 made of AlGaN in the GaN-based HEMT. In a conventional structure, the 2DEG is uniformly distributed in a transistor.

On the other hand, in the semiconductor device 100, Al in the spacer layer 13 in a portion lower than the gate electrode 18 is diffused into the channel layer 12 and the barrier layer 14 by laser annealing as described below. Thus, the concentration of the two-dimensional electron gas 20 in the portion lower than the gate electrode 18 is reduced as compared with that in the other portion, and high resistance is achieved in the portion lower than the gate electrode 18.

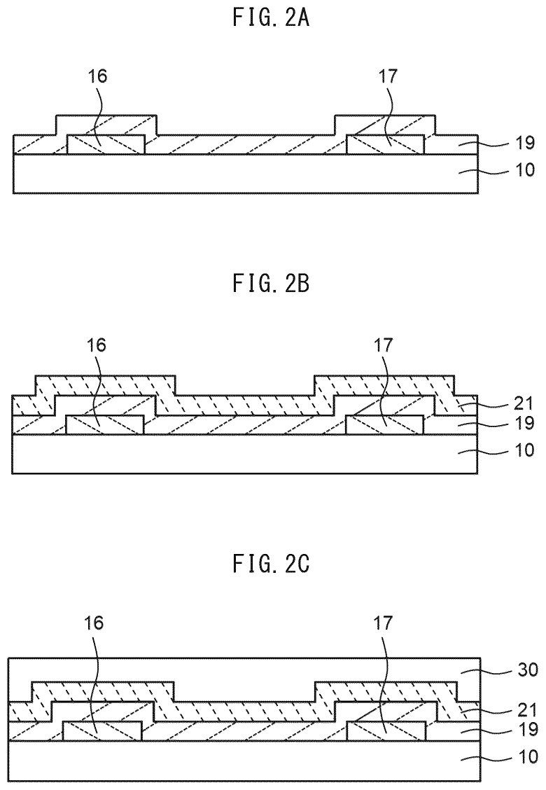

FIG. 2 to FIG. 5 are figures showing a method for manufacturing the semiconductor device 100 according to Embodiment 1. The method for manufacturing the semiconductor device 100 is described with reference to FIG. 2 to FIG. 5.

First, the channel layer 12, the spacer layer 13, the barrier layer 14, and the cap layer 15 are formed above the surface side of the substrate 11, above the channel layer 12, above the spacer layer 13, and above the barrier layer 14, respectively, by epitaxial growth to form the epitaxial wafer 10.

Then, as shown in FIG. 2A, the source electrode 16 and the drain electrode 17 are formed on a surface of the epitaxial wafer 10 by deposition, sputtering, plating, or the like. Subsequently, the protection film 19 is formed so that the epitaxial wafer 10 is covered. A material of the protection film 19 is, for example, a silicon nitride film, a silicon oxide film, an aluminum nitride film, or an aluminum oxide film, and formed by MOCVD or ALD (Atomic Layer Deposition), for example.

Then, as shown in FIG. 2B, a metal film 21 is formed so that the protection film 19 is covered. The metal film 21 is a thin metal film for reflecting a laser 90 which is to be described below. In Embodiment 1, a material of the metal film 21 is Ni, but not limited thereto and may be a metal such as Au.

Then, as shown in FIG. 2C, a resist 30 is applied so that the metal film 21 is covered.

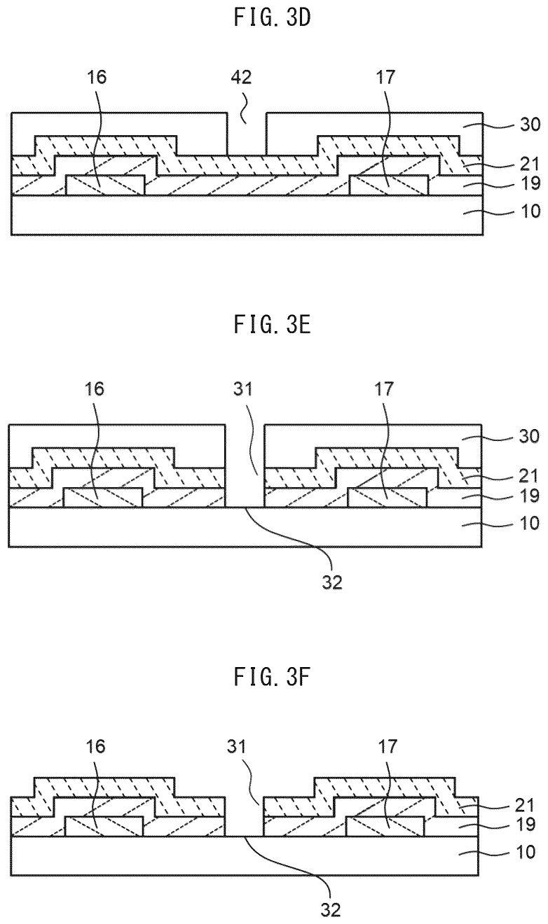

Then, as shown in FIG. 3D, a portion of the resist 30 where the gate electrode 18 is to be formed is removed by a so-called photoengraving process, which is typically used in semiconductor manufacturing, to form an opening 42 in the resist 30.

Then, as shown in FIG. 3E, the metal film 21 which is exposed from the opening 42 is opened by an etching process to form an opening portion 31 in the metal film 21. Further, the protection film 19 is removed to expose the epitaxial wafer 10. A portion of the epitaxial wafer 10 which is exposed from the opening portion 31 is referred to as an exposed portion 32. The opening portion 31 and the exposed portion 32 are formed as fine as the gate electrode 18 by a so-called photoengraving process.

Then, as shown in FIG. 3F, the resist 30 is removed by a wet etching process or a dry etching process.

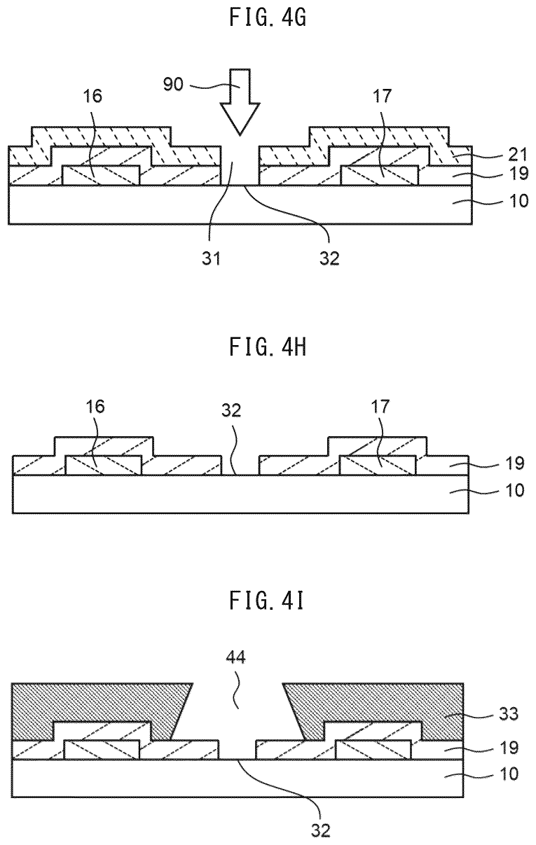

Then, as shown in FIG. 4G, the opening portion 31 is irradiated with the laser 90 to heat the exposed portion 32. As a result, the spacer layer 13 and the channel layer 12 in a portion lower than the exposed portion 32 are annealed. The wavelength of the laser 90 may be a wavelength at which GaN, AlGaN, AlN, or the like absorbs light, and is generally a wavelength shorter than 400 nm.

Then, as shown in FIG. 4H, the metal film 21 is removed by a wet etching process or a dry etching process.

Then, as shown in FIG. 4I, after a resist 33 is applied, an opening 44 is formed in the resist 33 by a photoengraving process. The opening 44 is an opening for forming the gate electrode 18 and is formed around the opening portion 31 and the exposed portion 32 while the opening portion 31 and the exposed portion 32 are exposed.

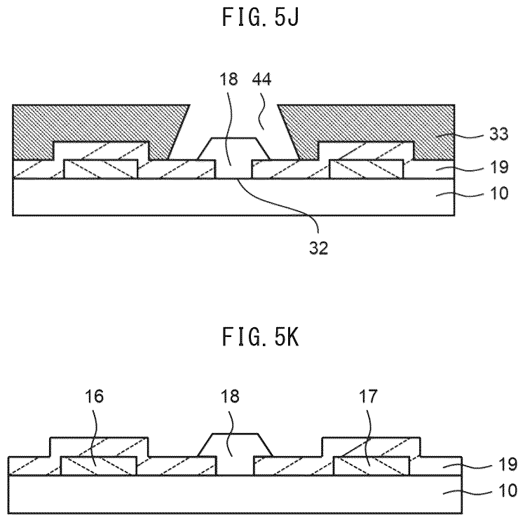

Then, as shown in FIG. 5J, the gate electrode 18 is formed in the opening portion 31. The gate electrode 18 is formed in contact with the exposed portion 32.

Then, as shown in FIG. 5K, the resist 33 is removed.

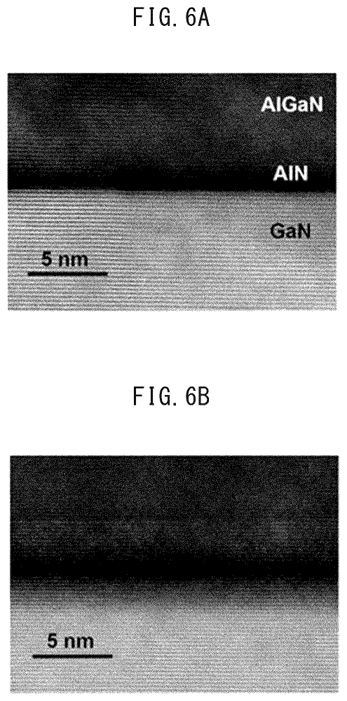

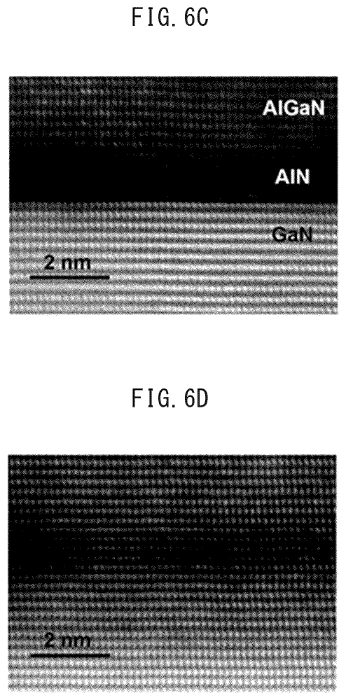

Next, the effect of annealing is described. FIG. 6 shows cross-sectional TEM images of observation before and after annealing of the vicinity of the interface between the channel layer 12 and the spacer layer 13 of the epitaxial wafer 10, and shows the state where Al in AlN is diffused by annealing. In FIG. 6, GaN, AlN, and AlGaN correspond to the channel layer 12, the spacer layer 13, and the barrier layer 14, respectively.

FIG. 6A and FIG. 6C are cross-sectional TEM images of the epitaxial wafer 10 before annealing, and FIG. 6B and FIG. 6D are cross-sectional TEM images of the epitaxial wafer 10 after annealing at 1140° C. for 5 minutes. FIG. 6C is an enlarged view of the neighborhood of the GaN/AlN interface in FIG. 6A, and FIG. 6D is an enlarged view of the neighborhood of the GaN/AlN interface in FIG. 6B.

From a comparison between FIG. 6A and FIG. 6B or a comparison between FIG. 6C and FIG. 6D, it can be seen that the clarity in the vicinity of the interfaces between the spacer layer 13 and the barrier layer 14 and between the channel layer 12 and the spacer layer 13 is lost by annealing. In particular, the change at the AlN/GaN interface is highly noticeable from the comparison between FIG. 6C and FIG. 6D.

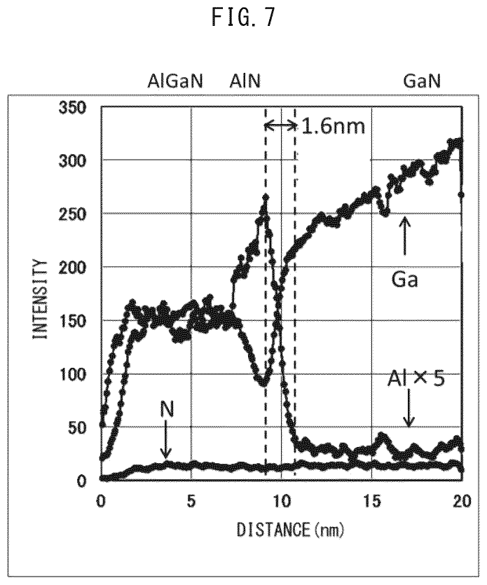

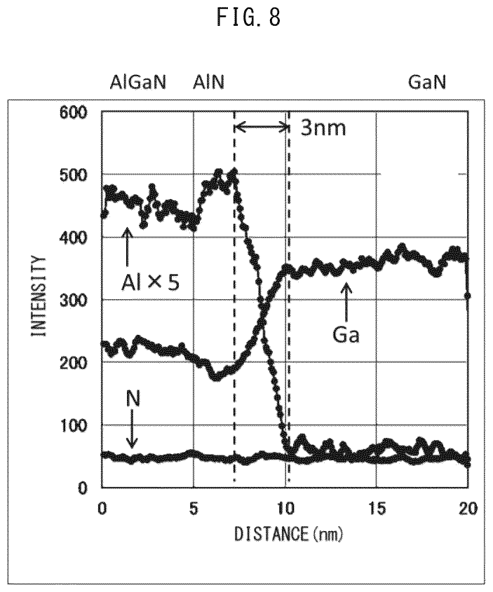

FIG. 7 shows the result of elementary analysis of the epitaxial wafer 10 before annealing, and FIG. 8 shows the result of elementary analysis of the epitaxial wafer 10 after annealing. In each of FIG. 7 and FIG. 8, the horizontal axis represents a distance from the surface of the wafer in a depth direction, and a barrier layer 14 side is shown on the left and a channel layer 12 side is shown on the right. Note that the horizontal axes of FIG. 7 and FIG. 8 do not represent absolute distances from the surface of the wafer, and therefore, positions cannot be directly compared with each other. The vertical axis represents the intensity of detected elements (Ga, N, and Al). Note that as for only Al, the intensity is multiplied by five and represented.

When a comparison of the intensity distribution of Al in FIG. 7 and FIG. 8 is made, the intensity of Al in FIG. 7 is sharply decreased in a 1.6 nm width from the location at a distance 9.2 nm to the location at a distance 10.8 nm in the figure. That is, it is indicated that the concentration distribution of Al is changed steeply. On the other hand, the intensity of Al in FIG. 8 is decreased in a 3 nm width from the location at a distance 7.2 nm to the location at a distance 10.2 nm in the figure. That is, it is indicated that the steepness is lost as compared with before annealing and Al in the spacer layer 13 is diffused into the channel layer 12 side after annealing.

Note that, though a part of Al in the spacer layer 13 is diffused also into the barrier layer 14, the concentration of Al in the channel layer 12 is significantly low as compared with the concentration of Al in the barrier layer 14; thus, it is considered that the amount of Al which is diffused from the spacer layer 13 into the channel layer 12 is remarkably larger than the amount of Al which is diffused from the spacer layer 13 into the barrier layer 14.

Next, the operation and the effect of the present disclosure are described.

In the semiconductor device 100, the opening portion 31 where the gate electrode 18 is to be formed is irradiated with the laser 90 in the state where the metal film 21 is left except in the opening portion 31. A material which can easily reflect the laser 90 is selected for the metal film 21, whereby only the exposed portion 32 of the surface of the epitaxial wafer 10 can be effectively heated.

Accordingly, in a portion lower than the opening portion 31 of the semiconductor device 100, the spacer layer 13 and the channel layer 12 are annealed, Al in the spacer layer 13 is diffused into the channel layer 12, and the concentration of the two-dimensional electron gas 20 is

On the other hand, the spacer layer 13 and the channel layer 12 are not annealed except in the portion lower than the opening portion 31 including a portion lower than the source electrode and the drain electrode. Thus, Al in the spacer layer 13 is not diffused into the channel layer 12, and the concentration of the two-dimensional electron gas 20 is not reduced.

It should be noted that the portion lower than the opening portion 31 herein includes not only directly below the opening portion 31 but also the vicinity directly below the opening portion 31 which is annealed by irradiating the opening portion 31 with the laser 90.

In other words, by irradiating the opening portion 31 where the gate electrode 18 is to be formed with the laser 90, Al in the spacer layer 13 is diffused into the channel layer 12 in the portion lower than the opening portion 31; consequently, the concentration of the two-dimensional electron gas 20 in the portion lower than the opening portion 31 is reduced as compared with the concentration of the two-dimensional electron gas 20 except in the portion lower than the opening portion 31.

As a result, the semiconductor device 100 achieves the effect of ensuring high withstand voltage by having high resistance in the portion lower than the gate electrode 18 while access resistance is reduced by providing the AlN spacer layer in the portion except the portion lower than the gate electrode 18.

Furthermore, in the manufacturing flow of the semiconductor device 100, the difficulty of removing the thin spacer layer 13 made of AlN by etching can be avoided.

Note that, though the protection film 19 is removed to expose the epitaxial wafer 10 in the above description of FIG. 3E, the protection film 19 may be left slightly to such a degree as not to affect annealing of the spacer layer 13 and the channel layer 12 by laser irradiation, and may be removed just before the formation of the gate electrode 18 which is described with FIG. 5J, for example. When the surface of the epitaxial wafer 10 is not exposed to an external atmosphere in this manner, the exposed portion 32 can be less damaged in the middle of steps.

The present disclosure is not limited to an example described above and includes various modified examples. For example, the example described above is described in detail to make the present disclosure easy to understand, and is not intended to necessarily limit the present disclosure to examples including all the configurations described. Furthermore, with respect to a portion of the configurations of the example, it is possible to add another configuration to it, remove it, and replace it with another configuration.

### REFERENCE SIGNS LIST

10 epitaxial wafer; 11 substrate; 12 channel layer; 13 spacer layer; 14 barrier layer; 15 cap layer; 16 source electrode; 17 drain electrode; 18 gate electrode; 19 protection film; 20 two-dimensional electron gas; 21 metal film; 31 opening portion; 32 exposed portion; 90 laser; 100 semiconductor device

1. A method for manufacturing a semiconductor device having a GaN-based HEMT comprising:
forming an epitaxial wafer including a channel layer and a spacer layer formed in contact with the channel layer;
forming a metal film on the epitaxial wafer;
forming an opening portion in the metal film;
irradiating the opening portion with a laser to anneal the spacer layer and the channel layer; and
forming a gate electrode in the opening portion.

2. The semiconductor device according to claim 1, wherein the spacer layer is made of AlN, and Al in the spacer layer is diffused into the channel layer by the annealing.

3. The semiconductor device according to claim 1, wherein the metal film is made of Ni or Au.

4. The semiconductor device according to claim 1, wherein a wavelength of the laser is shorter than 400 nm.

5. A semiconductor device having a GaN-based HEMT comprising:
an epitaxial wafer having a channel layer formed on a substrate and a spacer layer formed on the channel layer and containing Al; and
a gate electrode formed on the epitaxial wafer,
wherein the channel layer below the gate electrode contains the Al diffused from the spacer layer, and
the channel layer other than below the gate electrode does not contain the Al diffused from the spacer layer.

6. The semiconductor device according to claim 5, wherein the spacer layer is made of AlN.
